(19) United States
(12) Patent Application Publication
(10) Pub. No.: US 2022/0217878 A1
(43) Pub. Date: Jul. 7, 2022

(54) CABLE

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventors: HAN-RUN XIE, Huaian (CN); LU-YU CHANG, New Taipei (TW); A-NAN YANG, Huaian (CN)

(21) Appl. No.: 17/561,924

(22) Filed: Dec. 25, 2021

(30) Foreign Application Priority Data
Jan. 4, 2021 (CN) 202110002426.0

(51) Int. Cl. H05K 9/00

(52) U.S. Cl. CPC H05K 9/0098; H01B 11/00; H05K 9/0088

(57) ABSTRACT

A cable comprising: a core wires; a shielding layer covering the core wires; and an outer insulating layer covering the shielding layer; wherein the shielding layer is aluminum coated PP, or aluminum coated PE, or aluminum coated PTFE, or copper coated PP, or copper coated PE, or copper coated PTFE.

### BACKGROUND OF THE INVENTION

### 1. Field of the Invention

The present invention relates generally to a cable, and more particularly to a cable used to transmit high frequency signals.

### 2. Description of Related Arts

With the development and popularization of electronic technology products, signal cables are widely used in household appliances, instrumentation, automation equipment, data centers, servers, switches, cloud computing and 5G as a tool for signal transmission. However, in the signal transmission process, the cable is susceptible to interference from external electromagnetic signals, so it is often necessary to use a shielding structure to eliminate or reduce the interference of the external electromagnetic field and to prevent the leakage of the transmission signal. The traditional shielding layer is made of aluminum-coated PET (polyethylene terephthalate) material. However, the loss factor of PET material is relatively large, which affects signal transmission.

Therefore, it is necessary to provide an improved cable with strong anti-interference performance and better shielding effect.

### SUMMARY OF THE INVENTION

A main object of the present invention is to provide a cable, which has good shielding effect and stable signal transmission capability.

To achieve the above-mentioned object, a cable comprises: a pair of core wires; a shielding layer covering the core wires; and an outer insulating layer covering the shielding layer; wherein the shielding layer is aluminum coated PP, or aluminum coated PE, or aluminum coated PTFE, or copper coated PP, or copper coated PE, or copper coated PTFE.

Compared to prior art, the present invention uses aluminum coated PP, or aluminum coated PE, or aluminum coated PTFE, or copper coated PP, or copper coated PE, or copper coated PTFE, so that the signal attenuation value is small, and the reliability of signal transmission is ensured. Also, the cable of the present invention has the ability to transmit high-speed data signals with a frequency greater than 40 GHz.

### BRIEF DESCRIPTION OF THE DRAWING

FIG. 1 is the front view of a cable of the present invention; and

FIG. 2 is the test curve of the cable of the present invention and a traditional cable.

### DETAILED DESCRIPTION OF THE PREFERRED EMBODIMENT

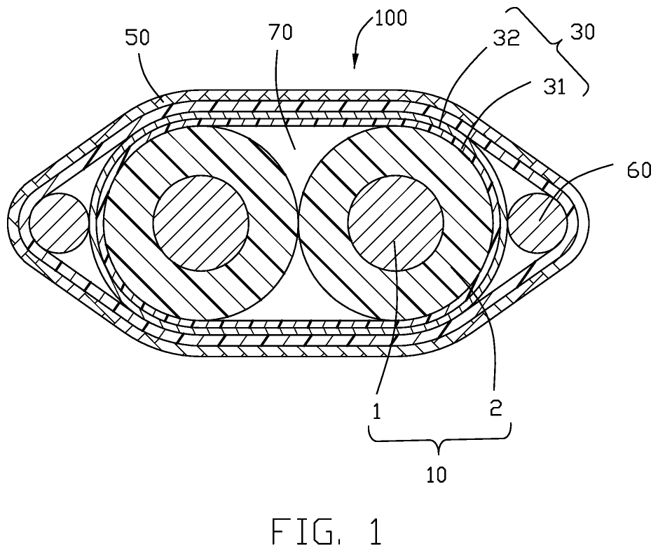

Referring to FIG. 1, which is a cable 100 of the present invention. The cable 100 includes a pair of core wires 10, a shielding layer 30 covering the core wires 10, an outer insulating layer 50 covering the shielding layer 30, and a ground wire 60 located between the shielding layer 30 and the outer insulating layer 50.

In this embodiment of two core wires 10, each core wire 10 includes an inner conductor 1 and an inner insulating layer 2 covering the inner conductor 1. The inner insulating layer 2 of each core wire 10 is extruded and molded to cover the inner conductor 1. The inner conductor 1 is used for transmitting high-speed signal. The inner insulating layers 2 of the two core wires 10 are in contact with each other. The shielding layer 30 is wrapping around the two core wire 10 in a longitudinal wrapping way or in a spiral winding way. The upper and lower sides between the shielding layer 30 and the two core wires 10 form air gaps 70. There are two ground wires 60, and the ground wires 60 are located on the left and right sides of the shielding layer 30, or located in the corresponding air gaps 70 on the upper and lower sides. The ground wire 60 can be only one. The shielding layer 30 can be one of Aluminum coated with PP (polypropylene), Aluminum coated with PE (polyethylene), Aluminum coated with PTFE (Polytetrafluoroethylene), Copper coated with PP, Copper coated with PE, Copper coated with PTFE. The shielding layer 30 is a PP layer 31 and a metal aluminum layer 32 formed on the PP layer 31, or a PE layer 31 and a metal aluminum layer 32 formed on the PE layer 31, or a PTFE layer 31 and a metal aluminum layer 32 formed on the PTFE layer 31, or a PP layer 31 and a metal copper layer 32 formed on the PP layer 31, or a PE layer 31 and a metal copper layer 32 formed on the PE layer 31, or a PTFE layer 31 and a metallic copper layer 32 formed on the PTFE layer 31. The aluminum layer 32 of the shielding layer 30 faces outward or the copper layer 32 faces outward. The outer insulating layer 50 can be provided as one layer or multiple layers, and its material can be PET (polyethylene terephthalate) tape. The outer insulating layer 50 is wrapped around the shielding layer 30 in a spiral winding way or a longitudinal winding way.

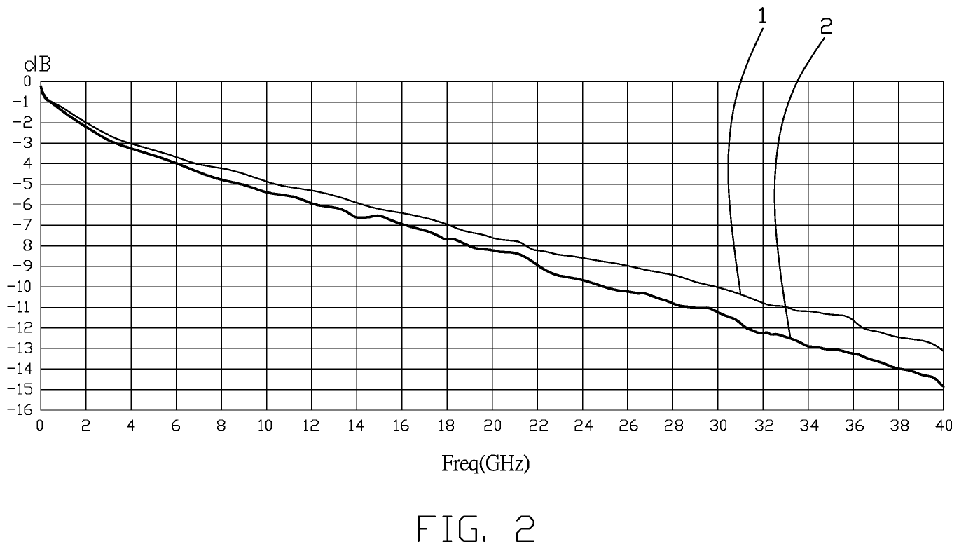

Please refer to FIG. 2, which is a comparison of the performance test curves of the cable of the present invention and the traditional cable, adopts the cable with the above structure and the wire gauge is 30. The measured result of the cable with the shielding layer of aluminum-coated PP is curve 1, and the measured result of the cable with the shielding layer of aluminum coated PET is curve 2.The abscissa is the frequency, unit in GHz, and the ordinate is the loss, unit in dB.

FIG. 2 is the SDD21 (Differential Insertion Loss) curve of the two cables. It can be seen that as the frequency increases, the differential insertion loss has no cliff-like attenuation before 40 GHz, and the attenuation of the cable with aluminum coated PP as the shielding layer is smaller than the attenuation of the cable with aluminum-coated PET as the shielding layer. And as the frequency increases, the gap between the two increases. The attenuation of the cable with aluminum coated PP as the shielding layer is less than −14 dB at 40 GHz. At a frequency of 40 GHz, the cable with aluminum-coated PP has a 2 dB lower attenuation than the cable with aluminum-coated PET.

The present invention uses aluminum coated PP, or aluminum coated PE, or aluminum coated PTFE, or copper coated PP, or copper coated PE, or copper coated PTFE as the shielding layer. The loss factor of PP, PE, PTFE material is smaller than that of traditional PET material, so the overall attenuation value of the cable is smaller, which improves the shielding effect. Compared with PET, PP material is lighter in weight and cheaper in price. The cable of the present invention has a high-speed data transmission capability with a signal transmission frequency greater than 40 GHz.

What is claimed is:

1. A cable comprising:
a pair of core wires;
a shielding layer covering the core wires; and
an outer insulating layer covering the shielding layer; wherein
the shielding layer is selected from the group consisting of aluminum coated PP, aluminum coated PE, aluminum coated PTFE, copper coated PP, copper coated PE, and copper coated PTFE.

2. The cable as claimed in claim 1, wherein the shielding layer is selected from the group consisting of a PP layer and a metal aluminum layer formed on the PP layer, a PE layer and a metal aluminum layer formed on the PE layer, a PTFE layer and a metal aluminum layer formed on the PTFE layer, a PP layer and a metal copper layer formed on the PP layer, a PE layer and a metal copper layer formed on the PE layer, and a PTFE layer and a metal copper layer formed on the PTFE layer.

3. The cable as claimed in claim 1, wherein the aluminum layer of the shielding layer faces outward or the copper layer of the shielding layer faces outward.

4. The cable as claimed in claim 1, wherein the outer insulating layer is a wrapping tape made of PET material having one or more layers.

5. The cable as claimed in claim 1, wherein the differential insertion loss of the cable is attenuated less than −14 dB at a frequency of 40 GHz.
